(19) United States
(12) Patent Application Publication
(10) Pub. No.: US 2011/0139207 A1
(43) Pub. Date: Jun. 16, 2011

(54) Thermoelectric Element

(76) Inventor: Geoffrey Alan Edwards, Queensland (AU)

(21) Appl. No.: 12/993,567

(22) PCT Filed: May 21, 2009
(86) PCT No.: PCT/AU09/00631

§ 371 Date: Feb. 16, 2011

(30) Foreign Application Priority Data
May 21, 2008 (AU) 2008902513

(51) Int. Cl. H01L 35/02; H01L 21/02

(52) U.S. Cl. 136/230; 438/54; 257/E21.002

(57) ABSTRACT

A thermoelectric element for use in a thermoelectric device, the thermoelectric element includes a porous substrate coated with one or more materials, at least one of which is a thermoelectric material. There is also a method for making a thermoelectric element including providing a porous substrate and applying a coating of a thermoelectric material to the porous substrate.

### FIELD OF THE INVENTION

The present invention relates to a thermoelectric element containing nanometre-sized features. In another aspect, the present invention relates to a method for forming a thermoelectric element containing nanometre-sized features.

### BACKGROUND TO THE INVENTION

The thermoelectric effect is the conversion of temperature differences to electric voltage, or the conversion of electric voltage to temperature differences. A thermoelectric device creates an electric voltage when there is a different temperature on each side of the device. A thermoelectric device creates a temperature difference when a voltage is applied to it. The thermoelectric effect can be used to generate electricity, to measure temperature, to cool objects, or to heat objects.

Thermoelectric devices for cooling and heating and for the generation of electricity have been known for many years. However, thermoelectric devices have not been cost competitive (except for limited or specialised applications) because of the lack of thermoelectric materials having appropriate thermoelectric properties. U.S. Pat. No. 5,550,387 in the name of Elsner and assigned to Hi-Z Corporation, the entire contents of which are herein incorporated by cross-reference, describes some of the difficulties encountered with thermoelectric materials. This patent also describes thermoelectric elements having a very large number of alternating layers of semiconductor material, the alternating layers having the same crystalline structure. This patent described one thermoelectric material as comprising a superlattice of Si, as a barrier material, and SiGe as a conducting material, both of which have the same cubic structure. Another thermoelectric material described in this patent comprises a superlattice of B-C alloys, the layers of which would be different stoichiometric forms of B-C but in all cases the crystalline structure would be alpha rhombohedral.

Other United States patents that have been assigned to Hi-Z Technology Inc include U.S. Pat. No. 6,096,964, 6,096,965, 6,828,579, 7,038,234 and 7,342,170. The entire contents of each of those patents are incorporated herein by cross-reference.

In all of the patents mentioned above, layers of the thermoelectric material are deposited on to a substrate. Deposition of the layers of the thermoelectric material occurs via molecular beam epitaxy or sputtering. The substrates that are used present flat surfaces for receiving the deposited layers of thermoelectric material. The substrates used include silicon wafers and flexible films of silicon or polyimides.

The work by Hi-Z is an example of thermoelectric materials that have nanometre-sized features. It uses a large number of alternating layers of materials, ˜10 nm thick, where the layers are essentially flat and parallel, deposited on a flat substrate. In the Hi-Z patents, the layers are oriented so that the electron flow in the thermoelectric element is parallel to the layers.

U.S. Pat. No. 7,342,169 in the name of Venkatsubramanian et al and assigned to Nextreme Thermal Solutions also describes thermoelectric elements having a large number of alternating layers which are of nanometre-sized thickness. The layers are also essentially flat and parallel, deposited onto a flat substrate. In this work, in contradiction to the Hi-Z work, the layers are oriented in the thermoelectric element so that the direction of electron movement is perpendicular to the layers. Specific materials include alternating layers of Bi₂Te₃ and Sb₂Te₃.

Various other workers have attempted to make improved thermoelectric materials with nano-scale features, e.g. Harman et al (U.S. Pat. No. 6,605,772). The most common effect of nanoscale features appear to be suppression of thermal conductivity, which may be achieved without a drop in electrical conductivity of similar proportion. Various mechanisms of phonon blocking have been proposed. Another effect that has been predicted theoretically and observed experimentally is an increased Seebeck coefficient that arises due to quantum confinement. This effect is predicted to increase as the dimension of the quantum confinement approaches, or drops below, the exciton Bohr radius.

In all the above prior work, the surface that is being deposited on is essentially smooth.

In general, the methods used for producing thermoelectric materials with nanometre-sized features are expensive and/or difficult to scale up. There is therefore a need for new methods and materials that are more commercially viable for production of high performance thermoelectric elements with nanometre-sized features.

Practical thermoelectric devices require thermoelectric films that are sufficiently thick to enable management of heat flow. Production of sufficiently thick thermoelectric films with nano-scale features is a challenge. In current conventional commercial devices the thermoelectric material may be about 1-2 mm thick. Making the devices thinner is desirable for lightness and reduced material use, however the thinner the material, the higher the heat flow across the device for a given temperature difference. This can create problems with thermal management since heat flow is typically limited at either the cold side (removal of heat) or the hot side (addition of heat). Various minimum thicknesses have been proposed for devices used in conventional applications, e.g. about 50 micrometres thick or about 100 micrometres thick have been proposed as minimum thicknesses.

Conventional methods of deposition, for example molecular beam epitaxy, and physical vapour deposition techniques such as magnetron sputtering, build up layers of material on a flat substrate. Whilst control of nano-scale layers can be achieved, it takes a long time to build up thickness. Therefore materials made using these methods generally have a small total thickness. Nano-layer thermoelectric materials are being commercialised by Nextreme, however these materials are only thin and are therefore only useful in limited applications where the heat flow across such thin materials can be managed. For example, applications with small temperature differences, and/or specialised heat removal systems. Hi-Z corporation have made thicker nanostructured devices by first depositing layered materials on a flat substrate, then cutting up the resultant materials and orientating them perpendicularly to the original flat plane. The cut up pieces must be stuck together. In this way they can make thicker devices with an ‘in-plane’ orientation of nanolayers. However this has obvious problems for larger scale manufacture, and the original planar substrate is generally incorporated into the device, leading to heat losses.

A range of patents and patent applications seek to protect methods for production of nanostructured thermoelectric whereby a porous scaffold is first produced, which is then filled with thermoelectric material. For example, U.S. Pat. Nos. 7,098,393 and 6,670,539. The filling generally proceeds from one side to the other. In these methods the size, amount and morphology of the thermoelectric material is set by the size, amount and morphology of the pores. These methods have difficulties in producing precisely controlled nanostructures since, for example, it may be difficult to get all of the pores exactly the same size. In addition, since the size of the pores sets the size of the thermoelectric material, the pores must be very small if the thermoelectric material is to be nano-scale. One proposed benefit of nano-scale features is quantum confinement leading to increased Seebeck coefficients. This benefit increases as the size of the confinement approaches or goes below the exciton Bohr radius. The exciton Bohr radius can be very small for many materials, e.g. ˜2.4 nm for ZnO. Pores of such small size create problems with transport of thermoelectric material or precursors of thermoelectric material. In these methods the porous scaffold may be removed. Porous materials with controlled porosity on the nano-scale, for example so-called MCM-41 silica materials and the like, can have significant amounts of solid material. If this solid is not removed, it obviously remains in the thermoelectric device, where it can conduct heat. This reduces the efficiency of the device. Therefore with many porous materials the original porous material must be removed in order to obtain an efficient device.

With the filling methods, it is also difficult to incorporate more advanced nanostructures such as nanolayers or quantum dots into the filled material.

US patent application US2007/0277866 describes forming thermoelectric elements comprising nanotubes of thermoelectric material. The nanotubes are created by first depositing a metal coating inside the pores of a template/substrate then the thermoelectric material may be deposited on top of the metal via electrodeposition. Within a particular thermoelectric element (i.e. a nanotube array) the nanotubes will comprise either an n-doped or a p-doped semiconductor composition. The nanotubes can be deposited by electrochemical deposition or by electrochemical atomic layer epitaxy, where a monolayer or sub-monolayer of each element is deposited sequentially from separate baths. One problem with electrochemical methods is the requirement for liquid flow into the pore structures. Since liquids are much higher density and viscosity than vapour, mass transport through porous structures is much more difficult. Slow and/or inefficient mass transport can lead to non-uniform deposition (non-uniform in terms of both composition and thickness) and/or impractically long cycle times. This particularly applies to electrochemical atomic layer epitaxy, where different liquids must be continually flushed in and out of the porous structure. Also the requirement to pre-coat the structure with metal and then remove the metal is not advantageous for large scale production. In this patent application the nano or quantum dimension of the thermoelectric material is set by the wall thickness of the nanotube. In this application there are no examples where materials have actually been fabricated or a thermoelectric effect measured.

Even with thermoelectric devices above the minimum useful thicknesses specified above, thermal management can still be an issue. To illustrate this point, a current device may be 2 mm thick and operate at a temperature difference of 200 K. It's thermal system is designed to manage 20 W/cm2. Reducing the thickness to 200 μm, i.e. by a factor of 10, would normally increase the heat flow by a factor of 10. However since the thermal system cannot cope with this, the temperature difference will decrease to limit the heat flow and the efficiency of the device will drop. One method that has been used to overcome this problem is to reduce the amount of thermoelectric material. The equation for heat flow via conduction is;

$$Q = \frac{kA Δ T}{t}$$

where k is the thermal conductivity, A is the area, ΔT is the temperature difference, and t is the thickness. The equation shows that if the thickness t is decreased by a factor of 10, Q can be maintained if the area A is also reduced by a factor of 10, i.e. only 10% of the device is actually thermoelectric material. This, however, can lead to losses via heat shunting across the gaps from the hot side to the cold side. One way of addressing this problem is to separate the sides via spacers (see FIG. 1). Insulating material may also be added in between the thermoelectric material. However it would be advantageous to have a better solution to this problem.

The present applicant does not concede that the prior art discussed in this specification forms part the common general knowledge in Australia or elsewhere.

Throughout the specification, the term “comprising” and its grammatical equivalents shall be taken to have an inclusive meaning unless the context of use indicates otherwise.

### DESCRIPTION OF THE INVENTION

It is an object of the present invention to provide an improved thermoelectric element, or at least to provide a commercially useful alternative. It is also an object of the present invention to provide an improved method for forming thermoelectric elements with nanometre-sized features, or at least to provide a commercially useful alternative.

In one aspect, the present invention provides a thermoelectric element for use in a thermoelectric device, the thermoelectric element comprising a porous substrate coated with one or more materials, at least one of which is a thermoelectric material.

The coating may completely coat the surface of the porous substrate. Alternatively, the coating may only partially coat the surface of the porous substrate.

In some embodiments, the porous substrate comprises a non-ordered porous substrate. By “non-ordered porous substrate” it is meant that the porous substrate has a pore structure with pores of varying sizes and pores that extend in many different directions. The pores are non-straight. The pores may twist or turn and represent a tortuous path.

In some embodiments, the thermoelectric element may include porosity after the porous substrate has been coated with the thermoelectric material. In these embodiments, coating of the porous substrate material does not completely fill the pore structure of the porous substrate material, thereby resulting in the thermoelectric element retaining porosity. It will be understood that, as the original pore structure of the substrate has been coated with the thermoelectric material, the porosity of the thermoelectric element will be somewhat lower than the porosity of the original, uncoated substrate.

The porous substrate may have a high surface area with pore sizes in the nanometer to micrometre range. If an essentially solid film is desired, pore size distributions and types are designed to achieve high volume fractions of solid throughout the film. Pore size distributions and types may also be designed to improve ingress and penetration of gaseous vapours used in the coating process. In the case of porous final materials, the pore size distributions and types may also be designed to minimise thermal conductivity through the structure.

The porous substrate may be specifically chosen in order to achieve a target volume fraction of thermoelectric material using a target coating thickness. Substrates with higher surface areas per unit volume will require thinner coatings compared to substrates with lower surface areas per unit volume, to achieve the same volume fraction of coating material. For example, an aerogel may have a surface area greater than 30 m²/cc. This material may only require a coating thickness of a few nanometers to achieve significant volume fraction of coating. In this case, quantum confinement effects and significant phonon blocking effects may be achieved by using only a single layer of material since the layer is of nanometer thickness. Some cellulosic-based papers may have a surface area of a few m²/cc. These require thicker coatings to achieve a significant volume fraction of coating. The thicker coatings enable more complex nanostructures to be set up, for example multiple nano-layer structures. Therefore the substrate may be designed to suit a designed or required final nanostructure.

In some embodiments, the porous substrate has a significant number of pores in the mesoporous range. For example, the porous substrate may have a significant number of pores in the range from 7 nm to 250 nm. The porous substrate may have a significant number of pores ranging from 20 nm to several μm.

The porous film or substrate may comprise a substrate that is formed with suitable porosity. The porous film may be free-standing. Alternatively, the porous film or substrate may be provided by forming a porous film or a porous layer onto a solid substrate.

In one embodiment of the present invention, the porous layer or substrate may be of high surface area. The surface area of the porous layer or substrate may be greater than 1 m²/g, or >10 m²/g, or >100 m²/g, or at least several hundred m²/g.

In some embodiments of the present invention, the porous substrate may comprise a porous substrate having a thickness of between ˜10 μm and ˜2 mm, more preferably between ˜50 μm and ˜1 mm.

Another embodiment of the present invention involves using porous frameworks with low volume fractions of solid. Using a porous framework having a lower volume fraction of solid results in the formation of a thermoelectric element that has a lower volume or amount of the original substrate or layer material therein. Thus, the final material will contain higher amounts of the material that is used in the film or coating. For example, the porous framework may have less than 20% solid, or less than 10% solid, or less than 5% solid. Part of the porous framework may be a reinforcement component, for example, fibres, whiskers, particles fibrous mat or tissue, and the like. It is preferable that this reinforcement be orientated in-plane, so that cross-plane heat transport across the device, through the reinforcement phase, is reduced. It is also preferable that the diameter of the reinforcement is less than the thickness of the thermoelectric material, so as to avoid a direct heat path between the hot side and the cold side, along the reinforcement.

In one embodiment, the porous substrate may comprise an aerogel. The aerogel may comprise a silica aerogel. As will be understood by persons skilled in the art, aerogels are highly porous solids derived from highly crossed linked wet gels. Aerogels are formed by nanometre sized particles randomly interconnected into an open cell network typically with a large degree of mesoporosity (>80%, approximately) and high surface area (>50 m²/g, approximately).

Another porous structure that can be used is a xerogel. Xerogels are similar to aerogels. According to one definition, xerogels are distinguished from aerogels by their processing method. Aerogels commonly require supercritical drying whereas xerogels are not produced using supercritical drying. Xerogels are normally denser than aerogels, i.e. their solid fraction is higher.

In another embodiment, the porous substrate may comprise an L₃ phase material. One suitable material may be a silicate L₃ material.

In another embodiment, the porous substrate may comprise a high internal phase emulsion polymer.

In other embodiments of the present invention, the porous substrate may comprise three dimensional pore structures. By three dimensional pore structures we mean pore structures that have pores oriented in three dimensions. Possible advantages of such structures are increased accessibility, and multiple orientations of structures put down on the porous film. Such structures may include layers of nanometer-thickness, or other nanometer-sized features that have orientation, e.g. rods, plates or wires.

Yet another embodiment of the invention involves using a porous substrate or coating with controlled ranges of pore sizes, sometimes called ‘hierarchical’ structures. An example of such a pore structure might be micrometer-sized channels that lead into channels of around 100 nm, which further lead to pores of around 10 nm, which might have roughness of the order of 2 nm. Such structures can combine high surface areas with good fluid access.

Yet another embodiment of the invention involves using a porous substrate or coating that is comprised of a skeleton or framework, where the coating is applied externally to the skeleton or framework. In other words, the surface of the coating increases with coating thickness. Examples of such skeletons or frameworks are shown in FIG. 2.

Yet another embodiment of the invention involves using a porous substrate or coating that is comprised of a solid with holes through it, where the coating is applied internally to the holes. In other words, the surface of the coating decreases with coating thickness. Examples of such skeletons or frameworks are shown in FIG. 3.

Yet another embodiment of the invention involves using a porous substrate or coating that is comprised of a solid structure which enables both internal and external coating, such as a network of tubes. Examples of such structures are shown in FIG. 4.

Yet another embodiment of the invention involves using a porous substrate or coating that is comprised of a solid structure which is essentially comprised of continuous surfaces or membranes (FIG. 5). Examples of these substrates include L₃ phase and high internal phase emulsion polymers.

Yet another embodiment of the present invention involves using a porous substrate that may be subsequently removed following coating, so that the final material contains much less of the original porous substrate material. An example of this is a carbon aerogel which may be removed by subsequent combustion. Other examples of porous substrates that could be removed by combustion include polymeric products such as papers, filter papers, membranes or the like. Cellulose-based forms of these are specific examples. Other substrates could be used which could alternatively be removed by combustion, dissolution, evaporation etc.

Yet another embodiment of the present invention involves using a porous substrate that has significant roughness at a nanometer scale. In previous prior art such as Hi-Z, Nextreme, and coating of PAA the substrate being coated is essentially smooth. Porous substrates such as aerogels and xerogels may be thought of as being comprised of ‘strings’ of nanoparticles. Their surfaces are therefore much rougher, on a nanometer scale, than flat substrates or smooth porous structures such as PAA.

Yet another embodiment of the present invention involves using a porous substrate that is essentially free of pores that provide a direct ‘line of sight’ from one electrode to the other, and particularly essentially free of pores that provide a direct ‘line of sight’ from one electrode to the other whilst being orientated close to perpendicularly to the electrodes. ‘Line of sight’ pores can provide a path for heat transfer via infra-red radiation and also heat transfer via convection. Tortuous pores can reduce infra-red heat transfer by providing infra-red absorbing solid between electrodes and can minimize convection.

Yet another embodiment of the present invention involves nano-layer structures that can utilize both cross-plane and in-plane effects. Cross-plane effects that are being targeted in the field include reduction of thermal conductivity, energy filtering effects and thermionic effects. Energy filtering and thermionic effects arise from using layers that provide potential barriers to carrier movement. The barriers are characterized by a height and a width.

FIGS. 6(a) and (b) show a highly magnified view of the surface of a nanolayered material of the present invention. At the top of the filament of porous substrate, the nanolayers wrap around. To make a device, a contact is placed on top. In FIG. 6(a) carriers (electrons for n-type, holes for p-type) must first pass across planes before they can begin travelling in-plane. This allows for cross-plane effects such as thermal conductivity reduction, energy filtering and thermionic effects. In FIG. 6(b) the surface has been removed by, for example, plasma etching. This enables direct contact to the layers, and therefore allows a device with much reduced or no cross-plane effects.

The material that is coated onto the porous substrate may contain nano-sized features that lead to quantum confinement effects such as increased Seebeck coefficients. Such effects are known to become significant when the size of the confinement approaches, or is less than, the Bohr exciton radius of the material.

In other embodiments, the nano-sized features may lead to decreased thermal conductivity, which may be due to increased phonon scattering at interfaces, or energy filtering, or other phonon blocking mechanisms associated with nano-scale features.

The material that is coated onto the porous substrate may be of nanometer thickness, i.e. the coating thickness may be measured in nanometers. Suitably, the coating may have a thickness of from 1 nm to 100 nm, more suitably 1 nm to 50 nm, even more suitably from 1 nm to 20 nm, even more suitably from 1 nm to 10 nm. The most suitable ranges of thickness of the coated material may be modified according to the exciton Bohr radius of the material, eg. the coating may have a thickness that is three times the exciton Bohr radius, or two times the exciton Bohr radius, or equal to the exciton Bohr radius, or less than the exciton Bohr radius. The optimal thickness to provide the optimal combination of Seebeck coefficient, thermal resistivity and electrical resistivity is expected to be dependent upon the material used in the coating.

In this case, quantum confinement may be achieved within the single layer, i.e. the dimension of the quantum confinement is the thickness of the layer. Alternatively or additionally, phonon-blocking effects may be achieved through the nano-metre scale thickness of the layer. These effects may be enhanced by providing a tortuous path.

The material that is coated onto the porous substrate may also comprise a plurality of layers of material. The plurality of layers may comprise a plurality of layers having a thickness in the nanometre range. The plurality of layers may comprise a plurality of layers of different materials. The plurality of layers may comprise alternating layers of different material. One or more of the materials should be a thermoelectric material. The thermoelectric material may comprise a semiconductor material. In this case quantum confinement may be achieved within a layer, i.e. the dimension of the quantum confinement may be the layer thickness. This may be in addition to any quantum effects from the total coating thickness. Alternatively or additionally, phonon-blocking effects may be achieved through the nano-metre features of the layers, either solely or in addition to the nano-scale thickness of the layer. These effects may be enhanced by providing a tortuous path.

The plurality of layers may comprise alternating layers of Si and SiGe, alternating layers of B-C of different compositions, such as B₄C and B₉C or even B₁₁C, or alternating layers of Si and SiC. Other thermoelectric materials, such as lead telluride or bismuth telluride thermoelectric materials coated onto a porous substrate, at least one of which is a thermoelectric material. The layers may also be comprised of more than two different materials. They may also be comprised of layers with different crystal structures. Other examples include layers of silicon carbide and boron carbide, where the boron carbide may have a range of compositions. The layers may be thermally stable.

Alternatively the plurality of layers may comprise alternating layers of doped zinc oxide material and other materials. For example, alternating layers of Al-doped zinc oxide and Al₂O₃, or alternating layers of Al-doped zinc oxide and ZnₓMg_{y}O_{z}, where the ZnₓMg_{y}O_{z} may be doped or undoped.

Alternating layers of cobalt-oxide based materials with other materials are also possible.

Both single layer and multi-layer coatings may incorporate quantum dots. In this case, quantum confinement may occur in the dimension of the quantum dot. It may also occur in the dimensions of the coating thickness, and/or the nanolayer thickness.

The material that is coated onto the porous substrate may be comprised of other nanometer-sized features such as quantum dots, rods, plates, wires, or combinations of these. Combinations of these with the alternating nanometer-thickness layers is also possible.

The material that is coated onto the porous substrate may have a surface ‘capping’ layer that provides a specific function. For example, a capping layer that quenches surface defects may provide increased electrical conductivity. Al₂O₃ capping layers have been shown to decrease the effects of surface defects in zinc oxide-based semiconductors.

The porous substrate may first be coated with a material that allows better nucleation of subsequent coated layers. It may also be coated with a ‘diffusion barrier’ material, prior to subsequent coating, to minimise diffusion of elements into and/or out of the porous substrate. Such diffusion may deteriorate the structure and hence performance. The porous substrate may also be first coated with a material or materials, including nanolayered materials, that act as thermal barriers. This coating may also perform any combination of nucleation, thermal barrier and diffusion barrier.

The material may be coated onto the porous substrate using any technique known to be suitable to the person skilled in the art. For example, the porous substrate may be coated with the thermoelectric material using atomic layer deposition (ALD). In ALD, precursors are added to a chamber at low pressure and form a monolayer on the surface. This monolayer acts as a barrier to further precursor deposition. The precursors are purged, then a reactant gas is added that reacts with the precursor monolayer to form a product that is able to accept another monolayer of precursor. Thus, areas that are more exposed to precursor gases receive exactly the same monolayer coating as areas that take longer to be exposed to precursors. It is known that films deposited by ALD may be ‘pinhole-free’ at much thinner thicknesses compared to other methods. ALD thereby offers control of layer deposition at an unparalleled fine scale. The coatings produced by ALD are commonly ‘conformal’, i.e. they conform to the shape of the substrate. Plasma-enhanced ALD is a variation of ALD that may also be used.

Other coating techniques may be suitable, such as chemical vapour deposition, physical vapour deposition, electron evaporation, sputtering and variations of these.

In a second aspect, the present invention provides a method for making a thermoelectric element comprising providing a porous substrate and applying a coating of a thermoelectric material to the porous substrate.

In some embodiments, the coating of thermoelectric material is supplied such that the porous structure of the substrate is not completely filled by the thermoelectric material. Therefore, the thermoelectric element formed by this embodiment of the method retains a degree of porosity in its final structure.

In some embodiments of the method, the method comprises forming a plurality of layers of thermoelectric material on the porous substrate. The layers of thermoelectric material may comprise layers of different material. The layers of different material may comprise alternating layers of different material.

The thermoelectric material may be deposited on the substrate using any technique known to be suitable to a person skilled in the art. One example of a suitable technique comprises atomic layer deposition.

Another embodiment of the present invention involves a coated porous substrate, in which significant porosity remains after coating, and which exhibits low thermal transport despite there being a relatively low amount of thermoelectric material being present. In one aspect of this embodiment, the volume fraction of porous substrate is low, so that the ratio of active thermoelectric material to porous substrate is increased. This is particularly important as the amount of thermoelectric material decreases. This embodiment is particularly relevant to commercial production of high performance thermoelectric materials at low cost. It has been found that higher performance thermoelectric materials such as some nanostructured thermoelectric materials are capable of carrying very high power densities, e.g. higher than 100 W/cm². This is a much higher power density than can be practically delivered to the device with heat transfer restrictions.

Also, as discussed previously, when using thinner devices, most applications require reduction of heat flow, which may be achieved by decreasing the area fraction of the thermoelectric material.

Therefore there is an opportunity in greatly reducing the amount of thermoelectric material required to produce a given output by using a much lower volume fraction of thermoelectric material in the thermoelement. Thus the heat flux in may be relatively low, but the ‘active heat flux’ through the thermoelectric materials is much higher due to its low volume fraction. For example, if 10 W/cm² heat is delivered to a thermoelement, and the thermoelement comprises only 10% thermoelectric material, the active heat flux may be ˜100 W/cm².

However practically this may be difficult to achieve without having considerable heat losses through heat transfer directly from the hot side to the cold side, i.e. heat transfer across without the heat going through and being harnessed by thermoelectric material. Coated nanoporous substrates provide a solution to this problem as structures such as aerogels, while very low in solid fraction, are amongst the most thermally insulating materials known to man. Thus a porous structure may be coated with an amount of thermoelectric material that leads to only a low total volume fraction of thermoelectric material, and still be very thermally insulating. In this case it is even more advantageous to have a low volume fraction of initial porous substrate, since the amount of thermoelectric material is smaller and thus the ratio of thermoelectric material to inert substrate is potentially higher.

Coated porous materials may be designed to inhibit thermal transfer via convection and infra-red radiation. Convection may be inhibited by utilising porous structures that have relatively small pores and tortuous paths. Infra-red radiation may be reduced by ensuring that there is no clear path from one side of the device to the other, in other words the infra-red radiation must pass through significant coating material before it gets to the other side. Use of thermoelectric materials that are good absorbers of infra-red radiation, such as doped ZnO, is useful in this respect. Use of contact metals that are low infra-red emitters, for example silver and aluminium, may also help.

To the best knowledge of the present inventors, atomic layer deposition has never previously been used to form thermoelectric materials. It is known that the properties of materials can vary significantly with deposition method. Indeed, atomic layer deposition can form materials that are quite different from materials with similar compositions deposited by other methods. Atomic layer deposition can form materials having larger amounts of amorphous material than other deposition techniques. Atomic layer deposition also can result in the formation of crystalline materials of differing structures or composition. Atomic layer deposition can deposit thin coatings with very small nanocrystals (i.e. nano-sized grains). Small grain sizes can be deleterious to thermoelectric properties. Also, hitherto, atomic layer deposition has only been used for very thin layers, typically less than tens of nanometers, which is much thinner than the thicknesses of typical thermoelectric materials in current devices (of the order of mm). Therefore, heretofore, atomic layer deposition has not been considered to be a suitable candidate for forming thermoelectric materials.

Atomic layer deposition into porous structures can also be problematical due to problems with penetration of gaseous precursors. This can lead to impractically long cycle times, or non-uniform coatings. A preferred method for coating via ALD is flow-through mode, where gaseous species are forced through the porous material. This can greatly reduce coating times and waste of precursor gas.

Accordingly, in yet another aspect, the present invention provides a method for making a thermoelectric element by depositing one or more materials onto a substrate wherein at least one of the materials is a thermoelectric material, characterised in that the one more materials are deposited by atomic layer deposition.

In any embodiment of this aspect of the present invention, atomic layer deposition may be used to deposit alternating layers of material, with at least one of the layers comprising a thermoelectric material. In another embodiment, atomic layer deposition is used to deposit a first layer of thermoelectric material, and then deposit a second layer of thermoelectric material. A plurality of alternating layers of first thermoelectric material and second thermoelectric material may be deposited. Quantum dots may also be formed using atomic layer deposition. These dots could be contained within alternating nanolayers.

In some embodiments, the substrate which is to be subjected to coating using atomic layer deposition comprises a porous material having small pores or tortuous pore paths through the substrate. ALD has encountered difficulties in coating such pore structures that can be considered as ‘high aspect ratio’ pore structures. Such structures can lead to excessively long processing times and/or non-uniform coatings, due to the large barrier to the diffusion of gaseous reactants or reactant species in and out of the substrate. The present inventors have surprisingly found that thermoelectric materials can be made using the combination of ALD with the specified substrates, and particularly when the substrates have practical thicknesses (>˜50 μm).

Also, hitherto, nanostructures deposited by ALD, such as nanolaminates, have been deposited on very flat, smooth, substrates. Many of the porous substrates in the present invention have very rough surfaces that would not be considered good substrates for growth of nanostructures such as nanolaminates.

It is an object of this invention to provide a useful method for producing thermoelectric materials. It is another object to provide a useful method for producing thermoelectric materials with nano-scale dimensions and/or nano-scale features. It is another object to provide a useful method for producing thermoelectric materials with nano-scale dimensions and/or nano-scale features, whereby the thermoelectric material is of a practically useful thickness. It is another object to provide a useful method for producing thermoelectric materials with nano-scale dimensions and/or nano-scale features, whereby the nano-scale features and/or dimensions are very tightly controlled.

It is a further object of the invention to provide thermoelectric materials comprised of a coated framework, whereby the coating is of nano-scale thickness. It is a further object that the nano-scale thickness is tightly controlled.

It is a further object of the invention to provide thermoelectric materials comprised of a coated framework, whereby the coating contains nano-scale features. It is a further object that the dimensions of the nano-scale features are tightly controlled.

It is a further object of the invention to provide thermoelectric materials comprised of a coated framework, whereby the coating contains nano-scale features or is of nano-scale thickness, where the dimensions of the nano-scale features and/or nano-scale thickness may or may not be tightly controlled, where the total thickness of the thermoelectric material structure is of practical thickness.

It is a further object of the invention to provide thermoelectric materials comprised of a coated framework, whereby the coating is an external coating on the framework.

It is a further object of the invention to provide a method for producing thermoelectric materials, whereby the thermoelectric materials are deposited as a coating onto a scaffold material, where the scaffold material has a low volume fraction and may be left in the device.

It is a further object of the invention to provide a thermoelectric material that may have a reduced volume fraction of thermoelectric material, whilst still providing good thermal insulation between the hot side and the cold side of the device.

### BRIEF DESCRIPTION OF THE FIGURES

FIG. 1. Diagram illustrating one method for reducing heat losses when the area fraction of thermoelectric material is low.

FIG. 2. Examples of porous frameworks that may be coated externally.

FIG. 3. Example of porous solids that may be coated internally.

FIG. 4. Examples of structures that may be coated both internally and externally Figure

FIG. 5. Example of a porous structure with a continuous membrane that may be coated.

FIG. 6. Schematic diagram showing contacts to nanolayered materials. In (a) the contact is put directly over the nanolayered materials and carriers must go across planes before they can travel along the planes. In (b) a layer of material has been removed by, e.g., plasma etching. The contact is now directly onto the planes, and cross-plane effects are reduced.

FIG. 7. Scanning electron micrograph of cross-section (fracture surface) of the material from example 1.

FIG. 8. Scanning electron micrograph of cross-section (fracture surface) of the material from example 2.

FIG. 9. Transmission electron micrograph showing the coating from example 2. The nanolayers can be seen in this micrograph.

FIG. 10. Dark-field transmission electron micrograph of the coating from example 2. The bright dots are nano-sized grains. The coating appears thicker than in FIG. 9 because in this micrograph the coating is inclined at an angle to the beam.

FIG. 11. Scanning electron micrograph of cross-section (fracture surface) of the material from example 6.

FIG. 12. EDS data showing Al (k) and Zn (k) integrated peak intensities across the full cross section of the film from example. 6.

FIG. 13. Scanning electron micrograph of cross-section (fracture surface) of the material from example 7.

FIG. 14. EDS data showing Al (k) and Zn (k) integrated peak intensities across the full cross section of the film from example. 7.

FIG. 15. Scanning electron micrograph of cross-section (fracture surface) of the material from example 9.

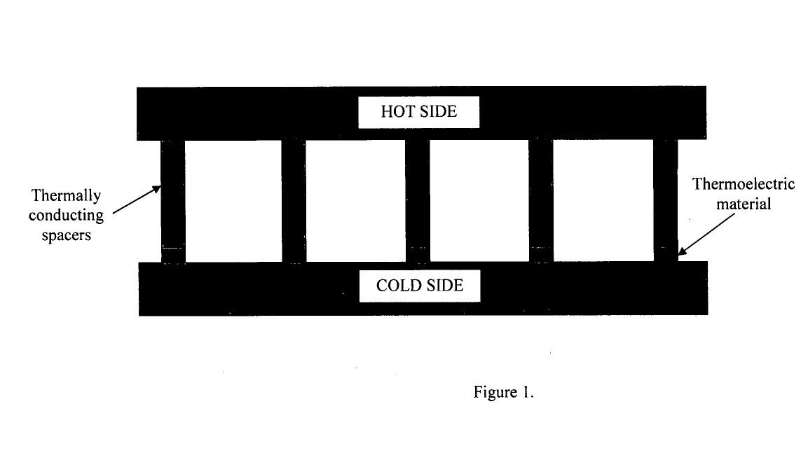

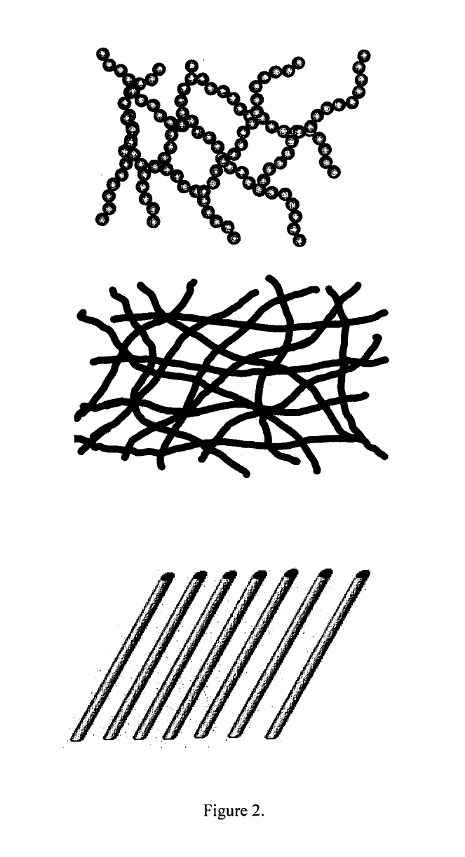

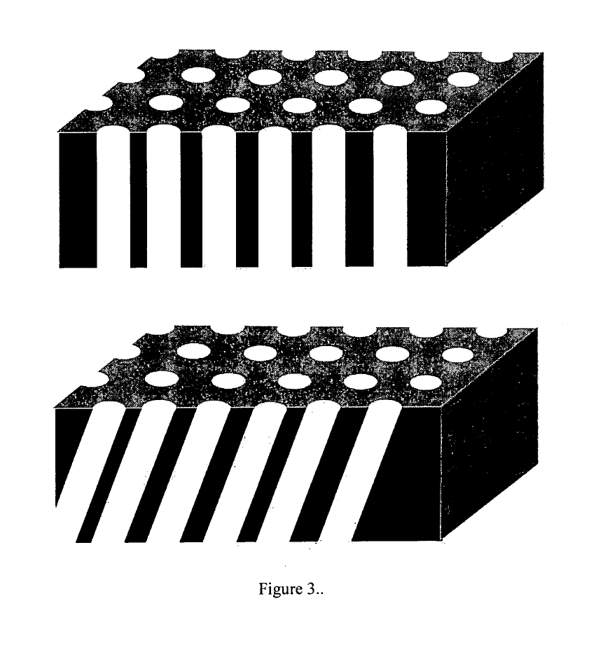

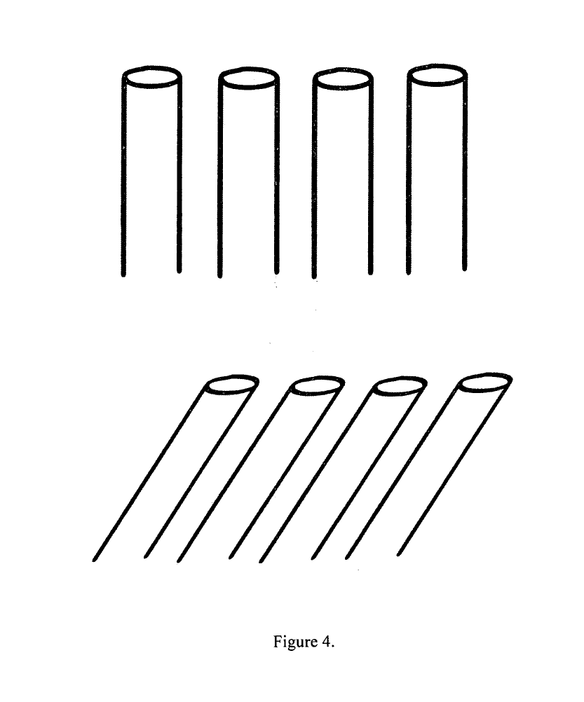

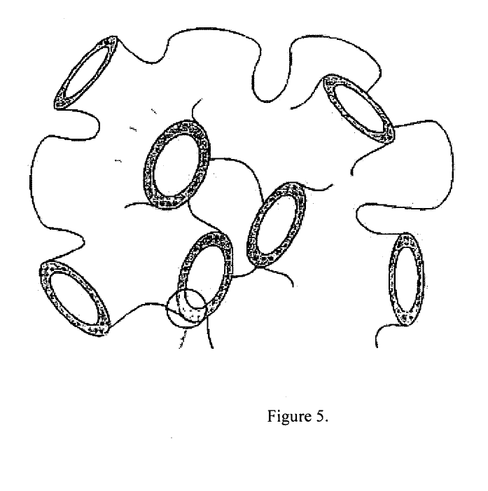

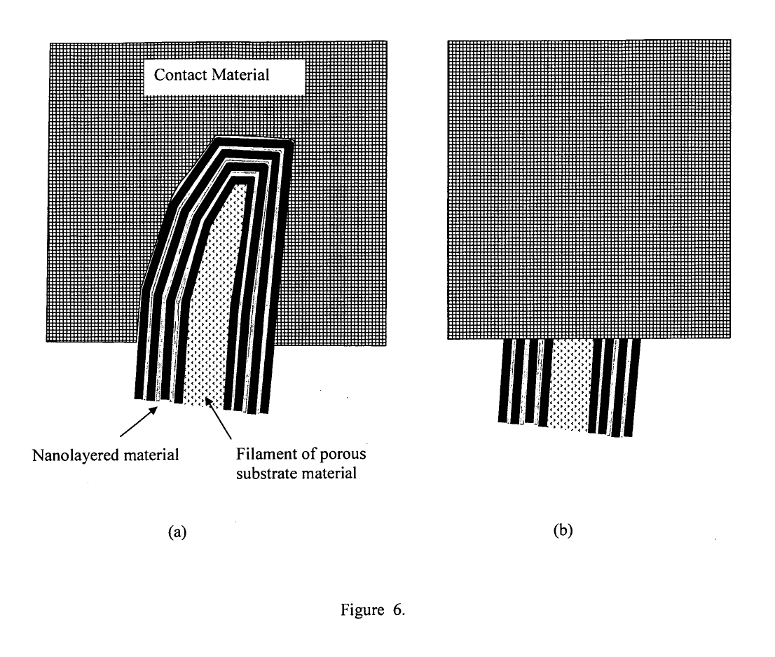

### EXAMPLES

### Example 1

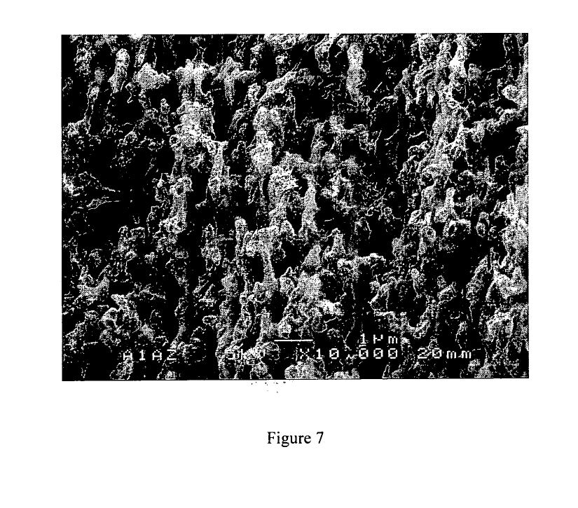

Cellulose acetate filter membrane material, thickness ˜130 μm, was coated with 1% Al-doped ZnO using flow-through ALD. A nucleating coating of Al₂O₃ was first put down on the material. The target coating thickness was ˜12 nm. From subsequent weight measurements, the volume fraction of coating was estimated to be ˜6%. FIG. 7 shows a scanning electron micrograph of a cross-section (fracture surface) of the coated material. From transmission electron microscopy the thickness of the coating was estimated to be very close to the target thickness.

### Example 2

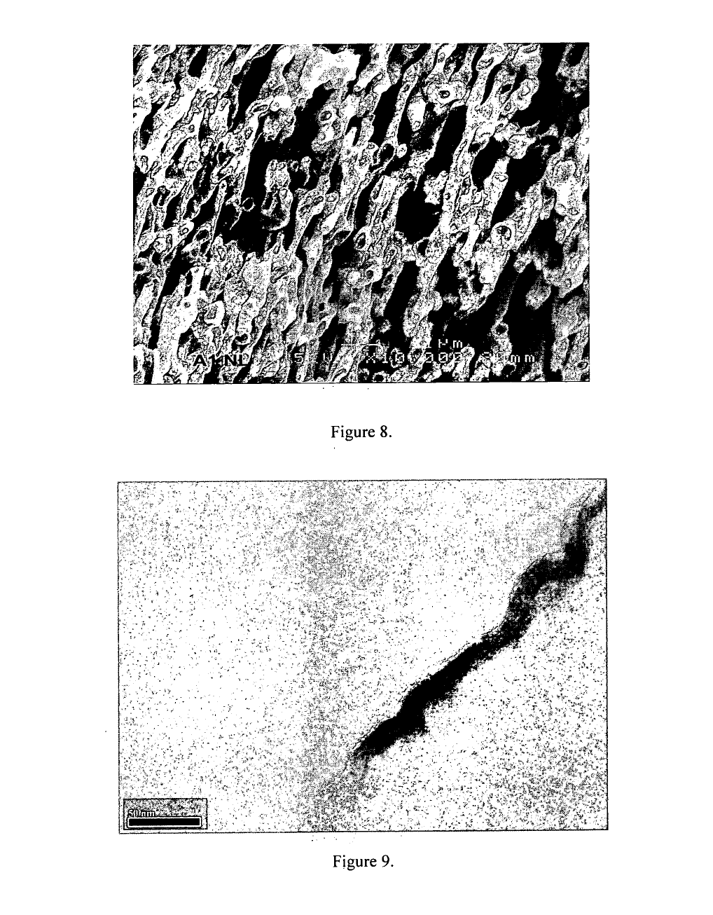

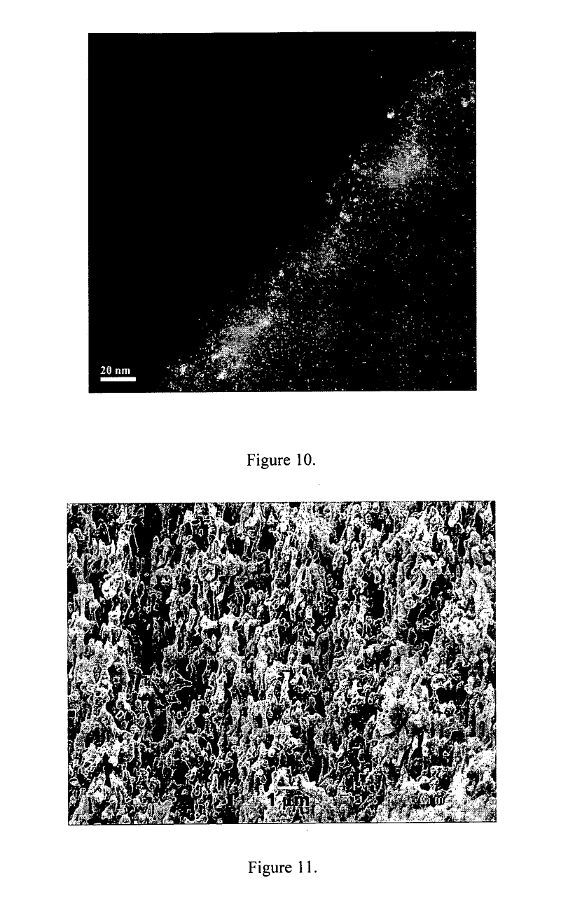

The cellulose acetate material from example 1 was coated with alternating nano-layers of 1% Al-doped ZnO, and Al₂O₃ using flow-through ALD. A nucleating coating of Al₂O₃ was first put down on the material. The target coating thickness was ˜12 nm. The final surface layer was Al₂O₃. From subsequent weight measurements, the volume fraction of coating was estimated to be ˜6%. FIG. 8 shows a scanning electron micrograph of a cross-section (fracture surface) of the coated material. FIG. 9 shows a transmission electron micrograph of the coating, indicating a coating thickness of ˜12 nm. The nanolayers can also be seen. The thickness of the Al-doped ZnO layers is estimated to be 3 nm and the thickness of the Al₂O₃ layer is less than 1 nm. FIG. 10 shows a dark field transmission electron micrograph of the coating showing nano-sized grains (bright). The apparent thickness of the coating in this micrograph is thicker than 12 nm because the coating is inclined to the beam.

### Example 3

Cellulose acetate material from example 1 was coated with 2% Al-doped ZnO using flow-through ALD, with a target coating thickness of ˜40 nm. A nucleating coating of Al₂O₃ was first put down on the material. From subsequent weight measurements, the volume fraction of coating was estimated to be 17.1%. Contacts were put on the specimen, one side was heated, and the voltage difference between hot and cold side measured to observe thermoelectric behavior. The results are listed in Table 1.

TABLE 1

| T low | T high | ΔV (mV) | ΔV/ΔT (μV/K) |
|---|---|---|---|
| 32 | 50 | −1.51 | −84 |
| 32 | 100 | −5.6 | −82 |
| 32 | 150 | −10 | −85 |
| 32 | 200 | −15.5 | −92 |
| 32 | 250 | −23.5 | −108 |
| 33 | 300 | −32.6 | −122 |
| 34 | 325 | −39.6 | −136 |

### Example 4

The cellulose acetate material from example 1 was coated with alternating nano-layers of 2% Al-doped ZnO, and Al₂O₃ using flow-through ALD. The target coating thickness was ˜40 nm. The final surface layer was Al₂O₃. From subsequent weight measurements, the volume fraction of coating was estimated to be 17.9%. Contacts were put on the specimen, one side was heated, and the voltage difference between hot and cold side measured to observe thermoelectric behavior. The results are listed in Table 2. Comparing the results in Table 2 with Table 1, the nanolayer material clearly has a much higher Seebeck coefficient (V/K) than the material with a homogenous coating.

TABLE 2

| T low | T high | ΔV (mV) | ΔV/ΔT (μV/K) |
|---|---|---|---|
| 25 | 50 | −10.7 | −428 |
| 25 | 100 | −30.5 | −407 |
| 26 | 150 | −51.3 | −414 |
| 27 | 200 | −78.8 | −455 |
| 29 | 250 | −120.8 | −547 |
| 30 | 300 | −161.5 | −598 |

A sample of this material was prepared and tested in the same way, except the surface was plasma-etched to a depth of ˜1 μm prior to deposition of contacts. The measurements are shown in Table 3. Clearly removal of the surface layer resulted in different Seebeck coefficients.

TABLE 3

| T low | T high | ΔV (mV) | ΔV/ΔT (μV/K) |
|---|---|---|---|
| 29 | 50 | −6.7 | −319 |
| 29 | 100 | −21.2 | −299 |
| 29 | 150 | −35.4 | −293 |
| 29 | 200 | −50 | −292 |
| 31 | 250 | −65 | −297 |
| 31 | 300 | −89.6 | −333 |

### Example 5

Cellulose acetate material from example 1 was coated with 2% Al-doped ZnO using flow-through ALD, with a target coating thickness of ˜20 nm. A nucleating coating of Al₂O₃ was first put down on the material. From subsequent weight measurements, the volume fraction of coating was estimated to be 9.4%. Contacts were put on the specimen, one side was heated, and the voltage difference between hot and cold side measured to observe thermoelectric behavior. The results are listed in Table 4.

TABLE 4

| T low | T high | ΔV (mV) | ΔV/ΔT (μV/K) |
|---|---|---|---|
| 26 | 60 | −3.6 | −106 |
| 26 | 100 | −7.3 | −99 |
| 26 | 150 | −12.2 | −98 |
| 27 | 205 | −18.6 | −104 |
| 27 | 250 | −26.6 | −119 |
| 29 | 306 | −37.7 | −136 |

### Example 6

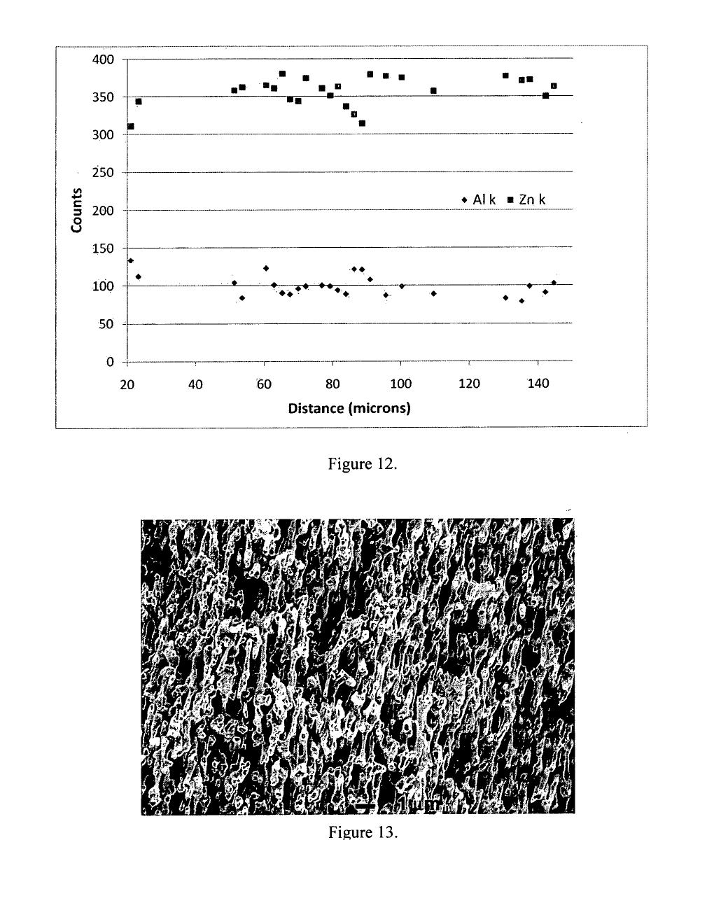

Cellulose nitrate filter membrane material, thickness 130 μm, was coated with 1% Al-doped ZnO using flow-through ALD. The target thickness was ˜12 nm. From subsequent weight measurements, the volume fraction of coating was estimated to be ˜6%. FIG. 11 shows a scanning electron micrograph of a cross-section (fracture surface) of the coated material. Energy dispersive spectroscopy (EDS) measurements indicated that the Zn and Al concentrations were similar through the thickness of the film (FIG. 12), indicating successful deposition. In FIG. 12 it is thought the composition fluctuations mainly result from morphology changes on the fracture surface. Poor penetration of precursors during ALD coating would lead to a constant decrease of the related element and this is not observed.

### Example 7

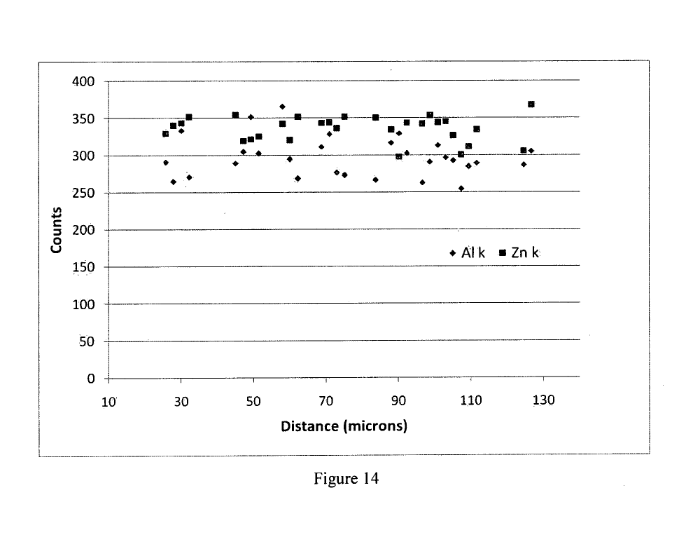

The cellulose nitrate material from example 5 was coated with alternating nano-layers of 1% Al-doped ZnO, and Al₂O₃ using flow-through ALD. The total thickness of the coating was targeted to be 12 nm. The final surface layer was Al₂O₃. From subsequent weight measurements, the volume fraction of coating was estimated to be ˜6%. FIG. 13 shows a scanning electron micrograph of a cross-section (fracture surface) of the coated material. Energy dispersive spectroscopy (EDS) measurements indicated that the Zn:Al ratio was similar through the thickness of the film (FIG. 14), indicating successful deposition. In FIG. 14 it is thought the composition fluctuations mainly result from morphology changes on the fracture surface. Poor penetration of precursors during ALD coating would lead to a constant decrease of the related element and this is not observed.

### Example 8

Cellulose nitrate filter membrane material from example 5 was coated with 2% Al-doped ZnO using flow-through ALD. The target coating thickness was 40 nm. From subsequent weight measurements, the volume fraction of coating was estimated to be 19.1%.

### Example 9

The cellulose nitrate material from example 5 was coated with alternating nano-layers of 2% Al-doped ZnO, and Al₂O₃ using flow-through ALD. The target coating thickness was 40 nm. The final surface layer was Al₂O₃. From subsequent weight measurements, the volume fraction of coating was estimated to be 20%. Contacts were put on the specimen, one side was heated, and the voltage difference between hot and cold side measured to observe thermoelectric behavior. The results are listed in Table 5. Similarly to the results in Example 4, this nanolayer sample shows high Seebeck coefficients.

TABLE 5

| T low | T high | ΔV (mV) | ΔV/ΔT (μV/K) |
|---|---|---|---|
| 26 | 50 | −10.6 | −442 |
| 26 | 100 | −36.9 | −499 |
| 27 | 150 | −64.2 | −522 |
| 28 | 200 | −88.8 | −516 |

A sample of this material was prepared and tested in the same way, except the surface was plasma-etched to a depth of ˜1 μm prior to deposition of contacts. The measurements are shown in Table 6. Clearly removal of the surface layer resulted in different Seebeck coefficients.

TABLE 6

| T low | T high | ΔV (mV) | ΔV/ΔT (μV/K) |
|---|---|---|---|
| 24 | 50 | −2.2 | −85 |
| 25 | 100 | −6.9 | −92 |
| 26 | 150 | −12 | −97 |
| 27 | 200 | −37.6 | −217 |
| 30 | 250 | −59.2 | −269 |
| 31 | 300 | −79.7 | −296 |

### Example 10

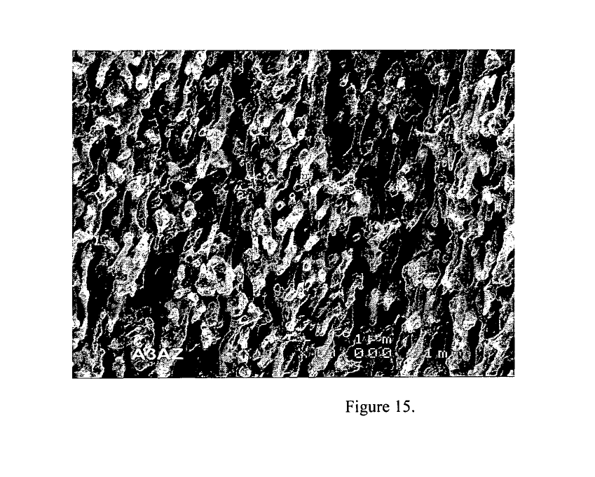

Cellulose filter membrane material, thickness ˜85 μm, was coated with 1% Al-doped ZnO using flow-through ALD. From subsequent weight measurements, the volume fraction of coating was estimated to be ˜6%. The thickness of the coating was targeted to be 12 nm. FIG. 15 shows a scanning electron micrograph of a cross-section (fracture surface) of the coated material.

### Example 11

The cellulose material from example 10 was coated with alternating nano-layers of 1% Al-doped ZnO, and Al₂O₃. The final surface layer was Al₂O₃. From subsequent weight measurements, the volume fraction of coating was estimated to be ˜6%. The total thickness of the coating was targeted to be ˜12 nm.

### Example 12

A free standing silica aerogel film was created, wherein the volume fraction of solid in the aerogel was ˜2%. The thickness of the film was ˜250 μm. The aerogel was reinforced with fiberglass, where the volume fraction of fiberglass reinforcement was 4%. The fibre diameter was ˜13 μm.

This film was coated with 2% Al-doped ZnO. Subsequent mass measurements indicated the volume fraction of coating was ˜5%.

### Example 13

The silica aerogel film of example 12 was coated with alternating nano-layers of 2% Al-doped ZnO, and Al₂O₃. The final surface layer was Al₂O₃. The surface of the material was plasma-etched to a depth of ˜1 μm. From subsequent weight measurements, the volume fraction of coating was estimated to be ˜6%. Contacts were put on the specimen, one side was heated, and the voltage difference between hot and cold side measured to observe thermoelectric behavior. The results are listed in Table 6.

TABLE 6

| T low | T high | ΔV (mV) | ΔV/ΔT (μV/K) |
|---|---|---|---|
| 25 | 50 | −3.5 | −140 |
| 27 | 100 | −7.8 | −107 |
| 31 | 150 | −11.5 | −97 |
| 37 | 200 | −21.6 | −133 |
| 44 | 250 | −49.7 | −241 |
| 57 | 300 | −73 | −300 |

Those skilled in the art will appreciate that the present invention may be susceptible to variations and modifications other than those specifically described. It will be understood that the present invention encompasses all such variations and modifications that fall within its spirit and scope.

1. A thermoelectric element for use in a thermoelectric device, the thermoelectric element comprising a porous substrate coated with one or more materials, at least one of which is a thermoelectric material.

2. A thermoelectric element as claimed in claim 1 wherein the coating completely coats the surface of the porous substrate.

3. A thermoelectric element as claimed in claim 1 wherein the coating only partially coats the surface of the porous substrate.

4. A thermoelectric element as claimed in claim 1 wherein the porous substrate comprises a non-ordered porous substrate.

5. A thermoelectric element as claimed in claim 1 wherein the porous substrate comprises a porous structure having essentially no pores that provide a line of sight passage from one side of the porous substrate to another side of the porous substrate.

6. A thermoelectric element as claimed in claim 1 wherein the thermoelectric element includes porosity after the porous substrate has been coated with the thermoelectric material.

7. A thermoelectric element as claimed in claim 1 wherein pore size distribution and type are designed to minimise thermal conductivity through the structure.

8. A thermoelectric element as claimed in claim 5 wherein the porous substrate is selected from an aerogel, a cellulosic-based paper, a xerogel or an L3 material or a high internal phase emulsion polymer.

9. A thermoelectric element as claimed in claim 5 wherein the porous substrate has a significant number of pores in the mesoporous range. from 7 nm to 250 nm.

10. A thermoelectric element as claimed in claim 1 wherein the porous substrate has a significant number of pores ranging from 20 nm to several μm.

11. A thermoelectric element as claimed in claim 1 wherein the porous substrate comprises a substrate that is formed with suitable porosity.

12. A thermoelectric element as claimed in claim 1 wherein the porous substrate is a free-standing film.

13. A thermoelectric element as claimed in claim 1 wherein the porous substrate is provided by forming a porous film or a porous layer onto a solid substrate or on a porous substrate.

14. A thermoelectric element as claimed in claim 1 wherein the porous substrate has a specific surface area of greater than 1 m²/g, optionally >10 m²/g, or optionally >100 m²/g, or optionally at least several hundred m²/g.

15. A thermoelectric element as claimed in claim 1 wherein the porous substrate comprises a porous substrates having a low volume fractions of solid.

16. A thermoelectric element as claimed in claim 15 wherein the porous substrate has less than 20% solid, or optionally less than 10% solid, or optionally less than 5% solid.

17. A thermoelectric element as claimed in claim 1 wherein at least part of the porous framework comprises a reinforcement component.

18. A thermoelectric element as claimed in claim 17 wherein the reinforcement component comprises one or more of fibres, whiskers, particles fibrous mat or tissue.

19. A thermoelectric element as claimed in claim 17 wherein the reinforcement component is orientated in-plane, so that cross-plane heat transport across the device, through the reinforcement phase, is reduced, and the diameter of the reinforcement is less than the thickness of the thermoelectric material, so as to avoid a direct heat path between a hot side and a cold side, along the reinforcement.

20. A thermoelectric element as claimed in claim 1 wherein the porous substrate is selected from the group comprising an aerogel, a xerogel, an L₃ phase material, a high internal phase emulsion polymer, three dimensional pore structures that have pores oriented in three dimensions, a porous substrate or coating with controlled ranges of pore sizes (‘hierarchical’ structures) a porous substrate or coating that is comprised of a skeleton or framework where the coating is applied externally to the skeleton or framework, a porous substrate or coating that is comprised of a solid with holes through it, where the coating is applied internally to the holes, a porous substrate or coating that is comprised of a solid structure which enables both internal and external coating, a porous substrate or coating that is comprised of a solid structure which is essentially comprised of continuous surfaces or membranes, a porous substrate that is subsequently removed following coating, so that the final material contains much less of the original porous substrate material, a porous substrate that has significant roughness at a nanometer scale.

21. A thermoelectric element as claimed in claim 20 wherein the porous substrate comprises a carbon aerogel which is removed by subsequent combustion or a polymeric products such as papers, filter papers, membranes, or a cellulose-based paper, filter paper, membrane or other substrates that are removed by combustion, dissolution, or evaporation.

22. A thermoelectric element as claimed in claim 1 wherein the material that is coated onto the porous substrate contains nano-sized features that lead to quantum confinement effects.

23. A thermoelectric element as claimed in claim 1 wherein the nano-sized features lead to increased Seebeck coefficient, decreased thermal conductivity, or energy filtering, or other phonon blocking mechanisms associated with nano-scale features.

24. A thermoelectric element as claimed in claim 1 wherein the material that is coated onto the porous substrate is of nanometer thickness.

25. A thermoelectric element as claimed in claim 1 wherein the material that is coated onto the porous substrate comprises a plurality of layers of material.

26. A thermoelectric element as claimed in claim 25 wherein the plurality of layers comprise a plurality of layers having a thickness in the nanometre range.

27. A thermoelectric element as claimed in claim 25 wherein the plurality of layers comprise a plurality of layers of different materials.

28. A thermoelectric element as claimed in claim 27 wherein the plurality of layers comprise alternating layers of different material and one or more of the materials comprise a thermoelectric material.

29. A thermoelectric element as claimed in claim 28 wherein the thermoelectric material comprises a semiconductor material.

30. A thermoelectric element as claimed in claim 29 wherein the quantum confinement is achieved within a layer, i.e. the dimension of the quantum confinement may be the layer thickness.

31. A thermoelectric element as claimed in claim 25 wherein a lower heat transfer rate through the thermoelectric element is enhanced by providing a tortuous path in the porous substrate.

32. A thermoelectric element as claimed in claim 28 wherein the plurality of layers comprise alternating layers of Si and SiGe, alternating layers of B-C of different compositions, or alternating layers of Si and SiC, or thermoelectric materials, such as lead telluride or bismuth telluride thermoelectric materials coated onto a porous substrate, at least one of which is a thermoelectric material or the layers are comprised of more than two different materials or the layers are comprised of layers with different crystal structures, or the layers comprise silicon carbide and boron carbide, where the boron carbide may have a range of compositions, or the plurality of layers comprise alternating layers of doped zinc oxide material and other materials, or the layers comprise alternating layers of Al-doped zinc oxide and Al₂O₃, or alternating layers of Al-doped zinc oxide and ZnₓMg_{y}O_{z}, where the ZnₓMg_{y}O_{z} may be doped or undoped, or the layers comprise alternating layers of cobalt-oxide based materials with other materials.

33. A thermoelectric element as claimed in claim 1 wherein the coating incorporates quantum dots.

34. A thermoelectric element as claimed in claim 1 wherein the material that is coated onto the porous substrate is comprised of other nanometer-sized features selected from quantum dots, rods, plates, wires, or combinations thereof or combinations of these with alternating nanometer-thickness layers.

35. A thermoelectric element as claimed in claim 1 wherein the material that is coated onto the porous substrate has a surface capping layer.

36. A thermoelectric element as claimed in claim 1 wherein the porous substrate is first b-coated with a material that allows better nucleation of subsequent coated layers or coated with a ‘diffusion barrier’ material, prior to subsequent coating, to minimise diffusion of elements into and/or out of the porous substrate.

37.-38. (canceled)

39. A method for making a thermoelectric element comprising providing a porous substrate and applying a coating of a thermoelectric material to the porous substrate.

40. A method as claimed in claim 39 wherein the coating of thermoelectric material is supplied such that the porous structure of the substrate is not completely filled by the thermoelectric material and the thermoelectric element formed retains a degree of porosity in its final structure.

41. A method as claimed in claim 40 wherein the method comprises forming a plurality of layers of thermoelectric material on the porous substrate.

42. A method as claimed in claim 41 wherein the layers of thermoelectric material comprise layers of different material.

43. A method as claimed in claim 42 wherein the layers of different material comprise alternating layers of different material.

44. A method for making a thermoelectric element comprising coating a porous substrate, in which significant porosity remains after coating, and which exhibits low thermal transport despite there being a relatively low amount of thermoelectric material being present.

45. A method as claimed in claim 44 wherein the volume fraction of porous substrate is low, so that the ratio of active thermoelectric material to porous substrate is increased.

46. A method as claimed in claim 44 wherein the coated porous materials inhibit thermal transfer via convection and infra-red radiation.

47. A method for making a thermoelectric element by depositing one or more materials onto a substrate wherein at least one of the materials is a thermoelectric material, characterised in that the one more of the materials are deposited by atomic layer deposition.

48. A method as claimed in claim 47 wherein the substrate comprises a porous substrate having small pores sizes and tortuous pore paths or essentially no straight pores therein.

49. A method as claimed in claim 47 wherein the atomic layer deposition is applied in flow through mode.

50. A method as claimed in claim 47 wherein the substrate comprises a porous film having a reinforcement material embedded therein.

51. A thermoelectric element as claimed in claim 1 wherein the thermoelectric material is produced by applying at least one layer by atomic layer deposition.

52. A thermoelectric element as claimed in claim 1 wherein the thermoelectric material comprises a porous substrate having a thickness of between ˜10 μm and ˜2 mm, more preferably between ˜50 μm and ˜1 mm.

53. A thermoelectric element as claimed in claim 1 wherein the thermoelectric material is deposited on the substrate in a thickness of from 1 nm to 100 nm, more suitably 1 nm to 50 nm, even more suitably from 1 nm to 20 nm, even more suitable from 1 nm to 10 nm.

54. A thermoelectric element as claimed in claim 1 wherein the thermoelectric element includes nano-layer structures that utilize both cross-plane and in-plane effects.

55. A thermoelectric element as claimed in claim 54 wherein the cross-plane effects include reduction of thermal conductivity, energy filtering effects and thermionic effects.

56. A thermoelectric element as claimed in claim 55 comprising a coating comprising a nanolayered material including a portion where said nano-layered coating wraps around, said thermoelectric element further comprising a contact placed over or above the nano-layered material.

57. A thermoelectric element as claimed in claim 55 comprising a coating comprising a nanolayered material including a portion where said nano-layered coating wraps around, said thermoelectric element further comprising a contact placed over or above the nano-layered material following removal of a surface portion of the nano-layered coating so that the contact makes direct contact with the layers of the coating.

58. A thermoelectric element as claimed in claim 1 wherein the coated material has a thickness that is three times the exciton Bohr radius, or two times the exciton Bohr radius, or equal to the exciton Bohr radius, or less than the exciton Bohr radius.
